(19) United States
(12) Patent Application Publication
(10) Pub. No.: US 2006/0061978 A1
(43) Pub. Date: Mar. 23, 2006

(54) Adapter plate for electrical boxes

(76) Inventor: Donald C. Palermo, Aurora, CO (US)

Correspondence Address: Richard C. Litman;LITMAN LAW OFFICES, LTD., P.O. Box 15035, Arlington, VA, 22215, US

(21) Appl. No.: 10/944,196

(22) Filed: Sep. 20, 2004

(51) Int. Cl. H05K 7/04

(52) U.S. Cl. 361/807

(57) ABSTRACT

The adapter plate for electrical boxes is designed to secure at least one receptacle within a multiple-gang nonmetallic electrical box. The plate provides for the reduction of an electrical box by one gang, for example, a two-gang electrical box to one gang or a three-gang box to two gangs. The adapter plate has a base portion and a receptacle-receiving enclosure. The base portion, having securing apertures defined therein, is adapted to allow the plate to be secured to the electrical box. The receptacle-receiving enclosure has bosses disposed on the top and bottom walls of the enclosure. The bosses have threaded bores defined therein that allow the receptacle to be attached to the adapter plate.

### BACKGROUND OF THE INVENTION

1. Field of the Invention

The present invention relates to adapter plates, and particularly to an adapter plate that reduces a multiple gang box by one gang.

2. Description of the Related Art

Electrical outlets, situated about homes, offices and the like, generally include a receptacle and an electrical box to which the receptacle is affixed. The electrical box is set within a wall and provides openings within the box through which electrical conductors may pass. The receptacle has multiple sockets to allow a user to make an electrical connection. The receptacle usually contains screw terminals that provide a contact point for the electrical conductors.

Many electrical boxes are one-gang boxes, providing enough space for one receptacle to be attached to the box. The electrical boxes may additionally be of a greater gang, depending on the needs of the user or the home or office unit. Electrical boxes that are two-gang boxes provide room for two receptacles and so on.

A problem that arises with the use of single gang electrical boxes is that the National Electrical Code regulates the number of conductors allowed within an electrical box based upon the cubic inch capacity of the box. In order to use more conductors, or larger gauge conductors, a larger electrical box must be employed. Therefore, more receptacles are needed. However, while more conductors may be needed, e.g., to extend a circuit, a greater number of receptacles may not needed nor be as aesthetically appealing to the homeowner.

While plates do exist that are mounted over the electrical box, their function is generally to provide for different electrical box configurations, different connection possibilities or a more aesthetically pleasing covering for the electrical outlet. Thus, a single outlet plate is not available for a two-gang electrical box. Likewise, a two outlet plate is not available for a three-gang electrical box, and so forth.

U.S. Pat. No. 5,189,259, issued Feb. 23, 1993 to S. Carson et al., describes a face plate assembly having a coupling plate and a face plate. The coupling plate and the face plate receive a wiring device, which is mounted onto a wall box. The coupling plate may be expanded to accommodate multiple wiring devices. U.S. Patent Publication No. 2003/0066674, published Apr. 10, 2003, describes a convertible electrical device cover that includes a base plate and an adapter plate. The base plate and adapter plate are configured to accommodate electrical devices.

Other adapter plates are described in U.S. patent Publication No. 2003/0137816, published Jul. 24, 2003 (outlet box assembly); U.S. Pat. No. 4,731,511, issued Mar. 15, 1988 to B. Steinhilber et al. (decorative wall plates an slider caps for toggle-type electrical switches); U.S. Pat. No. 4,835,343, issued May 30, 1989 to J. Graef et al. (two piece face plate for wall box mounted device); U.S. Pat. No. 4,892,485, issued Jan. 9, 1990 to V. Patton (adapter plate for converting a three phase meter socket for use with a single phase watt hour meter); U.S. Pat. No. 5,035,646, issued Jul. 30, 1991 to A. Ehrenfels et al. (flush mounted receptacle and plug with pin and sleeve type contacts); U.S. Pat. No. 5,135,411, issued Aug. 4, 1992 to R. Wiley et al. (multiple outlet receptacle and mountings therefore); U.S. Pat. No. 5,212,347, issued May 18, 1993 to C. Powers et al. (electrical apparatus cover plate); U.S. Pat. No. 5,773,760, issued Jun. 30, 1998 to T. Stark et al. (universal electrical cover); and U.S. Pat. No. 5,777,263, issued Jul. 7, 1998 to P. Maehler et al. (ground plate adapters).

Still other adapter plates are shown in U.S. Pat. No. 6,078,017, issued Jun. 20, 2000 to J. Blessitt et al. (adapter plate assembly for mounting a stored energy circuit breaker operator assembly); U.S. Pat. No. 6,508,445, issued Jan. 21, 2003 to R. Rohmer (gangable low voltage bracket for electrical devices); U.S. Pat. No. 6,511,343, issued Jan. 28, 2003 to M. Shotey et al. (receptacle-mounted cover plate to hide electrical socket face); U.S. Pat. No. 6,538,202, issued Mar. 25, 2003 to D. Shaffer (apparatus and method for covering electrical outlet boxes prior to sheetrocking); U.S. Pat. No. 6,616,005, issued Sep. 9, 2003 to R. Pereira et al. (modular faceplate assembly for an electrical box); U.S. Pat. No. 6,642,453, issued Nov. 4, 2003 to M. Shotey et al. (convertible electrical device cover and method for installing same); U.S. Pat. No. 6,679,725, issued Jan. 20, 2004 to B. Kidman (clip-on cover plate for electrical fixtures); and German Patent No. 19,860,407, published Jun. 29, 2000 (electrical cabinet with frame attached to base has adapter plate with attachment holders matching connection holders of frame to be attached for introduction into base end piece).

Although the related art addresses plates for electrical boxes, what is needed is an adapter plate for reducing a two-gang electrical box by one gang, such that one receptacle can attach to the electrical box in the center of the box.

None of the above inventions and patents, taken either singly or in combination, is seen to describe the instant invention as claimed. Thus an adapter plate for electrical boxes solving the aforementioned problems is desired.

### SUMMARY OF THE INVENTION

The adapter plate for electrical boxes of the present invention is designed to secure at least one receptacle within a multiple-gang nonmetallic electrical box. The plate provides for the reduction of an electrical box by one gang, for example, a two-gang electrical box to one gang or a three-gang box to two gangs. The adapter plate is affixed to the electrical box and mounted to a wall. A receptacle is placed within an opening in the adapter plate and affixed to the adapter plate.

The adapter plate has a base portion and a receptacle-receiving enclosure. The base portion has an upper portion and a lower portion opposite the upper portion. The receptacle-receiving enclosure has sidewalls extending perpendicular to and forward from the base portion. The enclosure rises above the base portion of the adapter plate to allow for drywall or spackle to be applied around the enclosure when the plate is installed.

Securing apertures are disposed along the upper and lower portions of the base portion. The securing apertures allow the adapter plate to be attached to the electrical box. Bosses are disposed on a top inner edge and bottom inner edge of the receptacle-receiving enclosure. The bosses each have a threaded bore defined therein. The bosses are therefore adapted to secure the receptacle to the adapter plate.

The adapter plate is particularly useful for a two-gang electrical box, but adapter plates may additionally be made for a three, four or greater gang box. The box has threaded bosses situated about the box edge. The adapter plate is affixed to the electrical box by threading screws through the securing apertures into the threaded bosses.

The adapter plate may be made from a plastic material or any other material suitable for use with a nonmetallic electrical box. The adapter plate may be designed to reduce the electrical box from two gangs to one gang, three gangs to two gangs, four gangs to three gangs, etc. The plate may enclose one receptacle, two receptacles, etc., depending on the number of gangs of the electrical box.

It is an object of the invention to provide an adapter plate that reduces a multiple-gang electrical box, and particularly a nonmetallic electrical box, by one gang.

It is an additional object of the invention to provide an adapter plate that allows a larger electrical box to be used with a given number of receptacles in order to permit a greater number of conductors to be connected within the electrical box.

It is a further object of the invention to provide an adapter plate to enable a user to use a larger electrical box and retain the same opening for a typical one-gang receptacle.

It is an object of the invention to provide improved elements and arrangements thereof for the purposes described which is inexpensive, dependable and fully effective in accomplishing its intended purposes.

These and other objects of the present invention will become readily apparent upon further review of the following specification and drawings.

### BRIEF DESCRIPTION OF THE DRAWINGS

FIG. 1 is an environmental, perspective view of an adapter plate for electrical boxes according to a first embodiment of the present invention.

FIG. 2 is an environmental, elevational front view of the adapter plate according to the first embodiment of the present invention attached to an electrical box and a receptacle.

FIG. 3 is an exploded, environmental view of the adapter plate according to the first embodiment of the present invention in relation to the electrical box and the receptacle.

FIG. 4A is an environmental perspective view of an adapter plate according to a second embodiment of the present invention with a three-gang nonmetallic electrical box.

FIG. 4B is an environmental perspective view of an adapter plate according to a third embodiment of the present invention with a four-gang nonmetallic electrical box.

Similar reference characters denote corresponding features consistently throughout the attached drawings.

### DETAILED DESCRIPTION OF THE PREFERRED EMBODIMENTS

The present invention is an adapter plate, designated generally as 10 in the drawings. The adapter plate is designed to secure at least one receptacle within a multiple gang electrical box, and more particularly, within a multiple gang nonmetallic electrical box. The adapter plate 10 reduces the gangs in the electrical box by one gang, for example, from a two-gang box to a single gang box, from a three-gang box to a two-gang box, etc.

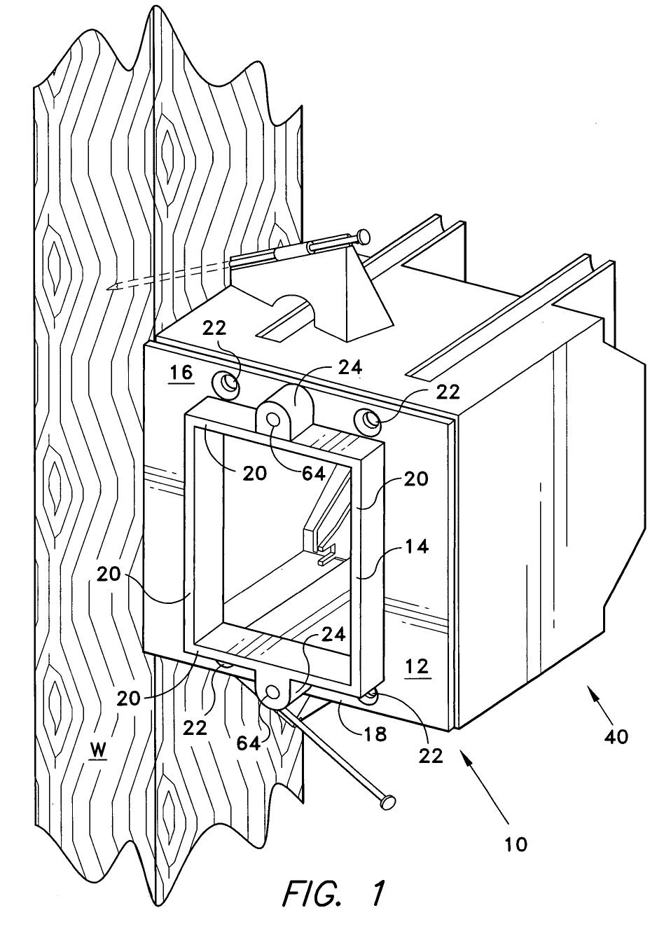

Referring first to FIG. 1, the adapter plate 10 is shown attached to the nonmetallic electrical box 40, which is positioned within a wall W. The adapter plate 10 has a base portion 12 and a receptacle-receiving enclosure 14. The base portion 12 has an upper portion 16 and a lower portion 18 opposite the upper portion 16. The receptacle-receiving enclosure 14 has a plurality of sidewalls 20 extending perpendicular and forward from the base portion 12. The receptacle-receiving enclosure 14 extends about one-half inch from the surface of the base portion 12. However, the height of the enclosure 14 is not critical and may be greater than or less than one-half inch. The enclosure 14 extends from the base portion 12 of the adapter plate 10 to allow for drywall or spackle to be applied around the enclosure 14 when the plate 10 is installed.

A plurality of securing apertures 22 or screw holes are defined along the upper portion 16 of the base portion 12 and the lower portion 18 of the base portion 12. The securing apertures 22 allow the adapter plate 10 to be attached to the electrical box 40, being aligned with the receptacle securing screw bosses of a conventional two-gang nonmetallic electrical box 40. A plurality of bosses 24 are disposed on at least one sidewall 20 of the receptacle-receiving enclosure 14. The bosses 24 each have a threaded bore 64 defined therein. The bores 64 defined within the bosses 24 allow the receptacle 30 to be secured to the adapter plate 10.

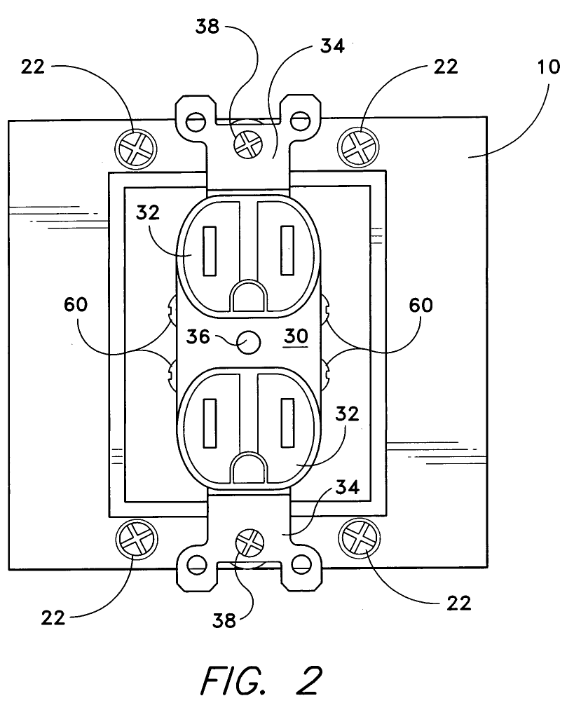

Turning now to FIG. 2, a front view of the adapter plate 10 attached to the electrical box 40 is shown. Additionally, the receptacle 30 is shown affixed to the adapter plate 10. The receptacle 30 has a plurality of sockets 32, a plurality of ears 34 that extend from the top and the bottom of the receptacle 30, a middle aperture 36, a plurality of ear apertures 38 located on the ears 34, and a plurality of terminals 60 situated on opposite sides of the receptacle 30.

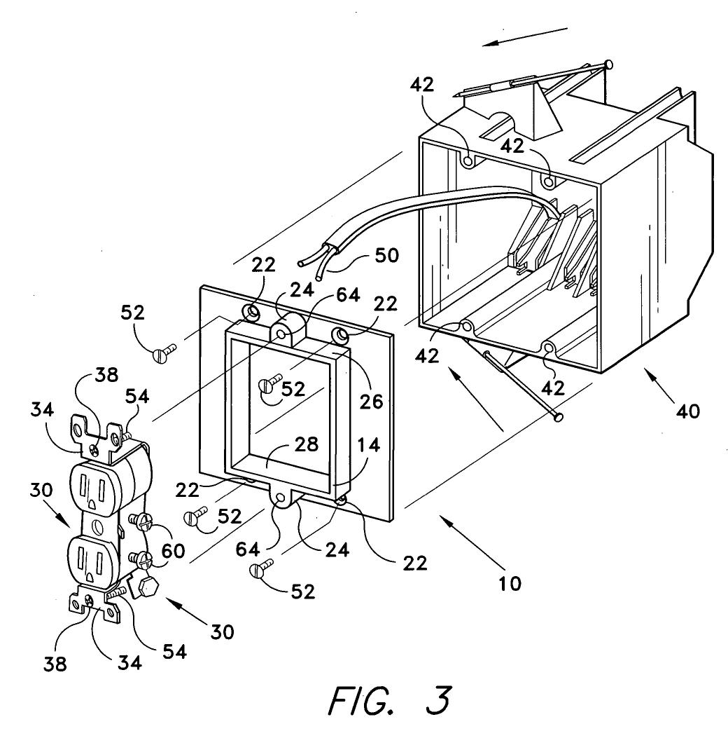

FIG. 3 shows an exploded view of the nonmetallic electrical box 40, the adapter plate 10, and the receptacle 30. The electrical box 40 is a two-gang electrical box. In alternate embodiments, the electrical box 40 may be a three-, four- or greater gang box. The box 40 includes a plurality of threaded mounting bosses 42. The securing apertures 22 of the adapter plate 10 are adapted to align with the threaded mounting bosses 42. The bosses 24 of the adapter plate 10 are disposed on a top sidewall 26 and a bottom sidewall 28 of the receptacle-receiving enclosure 14. Each boss 24 has a threaded bore 64 defined therein.

A first set of screws 52 is threaded through the securing apertures 22 on the adapter plate 10 into the threaded mounting bosses 42 on the electrical box 40, attaching the adapter plate 10 to the electrical box 40. A second set of screws 54 is threaded through the ear apertures 38 of the receptacle 30 and into the bores 64 defined within the bosses 24, attaching the receptacle 30 to the adapter plate 10.

Conductors 50 running through the electrical box 40 contact the terminals 60 on the receptacle 30 for electrical connection after the receptacle 30 is attached to the plate 10 and the plate 10 is attached to the box 40.

The adapter plate 10 may be made from a plastic material or any other material suitable for use with a nonmetallic electrical box 40.

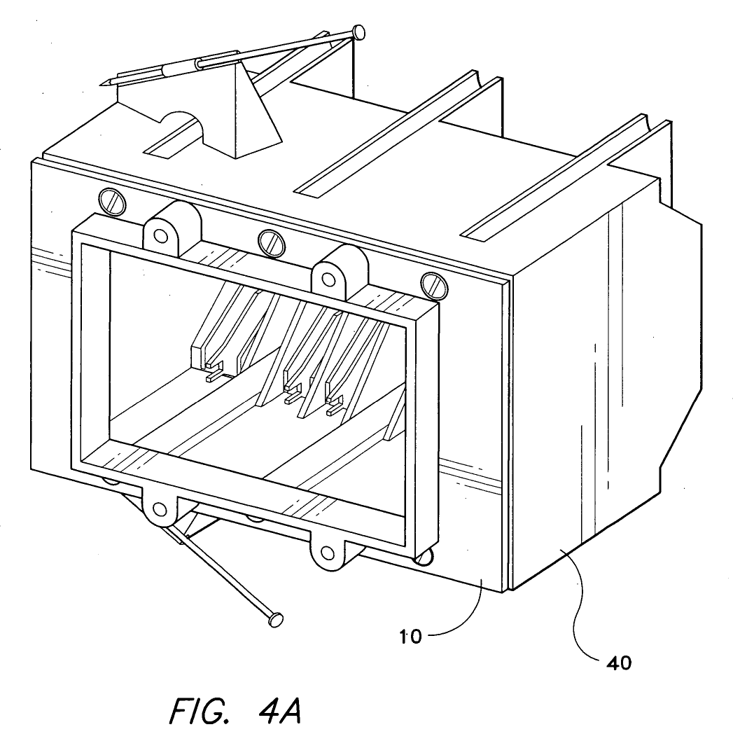

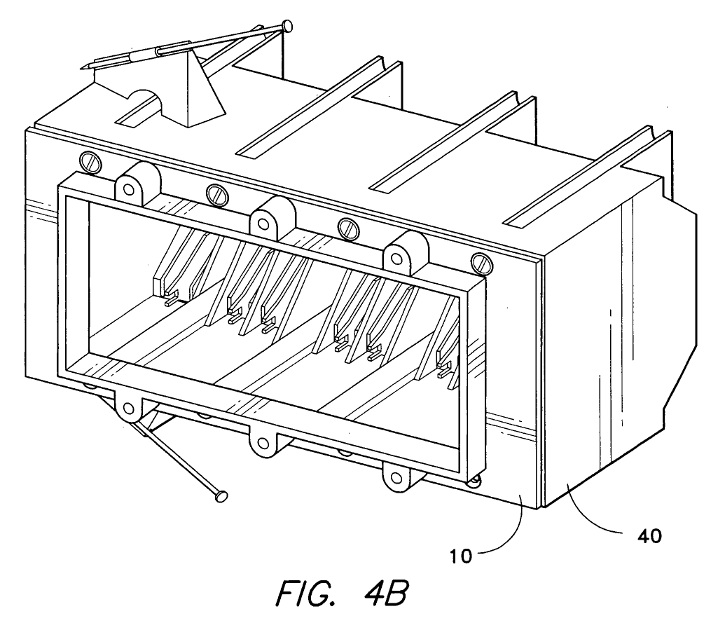

FIG. 4A shows an adapter plate 10 designed to reduce an electrical box 40 from three gangs to two gangs. Two receptacles 30 (not shown) are able to be secured to the adapter plate 10 for use with the electrical box 40 having three gangs. FIG. 4B shows an adapter plate 10 designed to reduce an electrical box 40 from four gangs to three gangs. Three receptacles 30 (not shown) are able to be secured to the adapter plate 10 for use with the nonmetallic electrical box 40 having four gangs.

It is to be understood that the present invention is not limited to the embodiments described above, but encompasses any and all embodiments within the scope of the following claims.

I claim:

1. An adapter plate for securing at least one receptacle within a multiple-gang nonmetallic electrical box, comprising:
a base plate having a plurality of securing apertures defined therein adapted for alignment with receptacle lugs on the electrical box; and
at least one receptacle-receiving enclosure having a plurality of sidewalls and at least one boss attached to one of the sidewalls, the boss having a threaded bore defined therein adapted for securing the receptacle to the adapter plate.

2. The adapter plate according to claim 1, wherein the base and the receptacle-receiving enclosure are made from a plastic material.

3. The adapter plate according to claim 1, wherein said plurality of sidewalls includes a top sidewall and an opposing bottom sidewall, said at least one boss comprising a first boss and a second boss disposed on the top and bottom sidewalls, respectively.

4. The adapter plate according to claim 1, wherein said at least one receptacle-receiving enclosure consists of two receptacle-receiving enclosures, the adapter plate being adapted for securing two receptacles within a three-gang nonmetallic electrical box.

5. The adapter plate according to claim 1, wherein said at least one receptacle-receiving enclosure consists of three receptacle-receiving enclosures, the adapter plate being adapted for securing three receptacles within a four-gang nonmetallic electrical box.

6. An adapter plate for securing at least one receptacle within a multiple-gang nonmetallic electrical box, the electrical box having a plurality of threaded mounting lugs defined therein, the adapter plate comprising:
a base having an upper portion and a lower portion opposite the upper portion, the base having a plurality of securing apertures defined therein along the upper portion and the lower portion adapted for alignment with the mounting lugs; and
at least one receptacle-receiving enclosure having a plurality of sidewalls extending perpendicular to and forward from the base and at least one boss having a threaded bore defined therein adapted for attaching the receptacle to the adapter plate, the boss being disposed along one of the sidewalls of the receptacle-receiving enclosure.

7. The adapter plate according to claim 6, wherein the receptacle-receiving enclosure extends about one-half inch from the base.

8. The adapter plate according to claim 6, wherein the base and the receptacle-receiving enclosure are made from a plastic material.

9. The adapter according to claim 6, wherein said plurality of sidewalls includes a top sidewall and an opposing bottom sidewall, said at least one boss comprising a first boss and a second boss disposed on the top and bottom sidewalls, respectively.

10. The adapter plate according to claim 6, wherein said at least one receptacle-receiving enclosure consists of two receptacle-receiving enclosures, the adapter plate being adapted for securing two receptacles within a three-gang nonmetallic electrical box.

11. The adapter plate according to claim 6, wherein said at least one receptacle-receiving enclosure consists of three receptacle-receiving enclosures, the adapter plate being adapted for securing three receptacles within a four-gang nonmetallic electrical box.
